(19) United States
(12) Patent Application Publication
(10) Pub. No.: US 2026/0140171 A1
(43) Pub. Date: May 21, 2026

(54) HIGH SPEED COMPARATOR BASED SUPPLY GLITCH DETECTOR

(71) Applicant: QUALCOMM Incorporated, San Diego, CA (US)

(72) Inventors: Khaled Mohamed Ashraf ELGAMMAL, Cork (IE); Mahmoud ELHEBEARY, San Diego, CA (US); Bo PANG, Carlsbad, CA (US); Khosrov DABBAGH SADEGHIPOUR, Cork (IE)

(21) Appl. No.: 18/949,754

(22) Filed: Nov. 15, 2024

(51) Int. Cl. G01R 31/317

(52) U.S. Cl. CPC G01R 31/31703; G01R 31/31721; G01R 31/31727

(57) ABSTRACT

Systems and techniques are described for providing a power supply glitch detector. For example, a computing device can generate (e.g., using a first supply scale-down engine connected to a power supply) based on a lower voltage threshold, a first voltage close to a reference voltage, compare (e.g., using a first comparator) the first voltage with the reference voltage, and generate, based on determining the first voltage is less than the reference voltage, a low flag indicating detection of a fault in the power supply. The computing device can generate (e.g., using a second supply scale-down engine connected to the power supply), based on an upper voltage threshold, a second voltage close to the reference voltage, compare (e.g., using a second comparator) the second voltage with the reference voltage, and generate, based on determining the second voltage is greater than the reference voltage, a high flag indicating detection of the fault.

### FIELD

The present disclosure generally relates to a power supply glitch (e.g., fault) detector. For example, aspects of the present disclosure relate to a high speed comparator-based supply glitch detector (e.g., to detect a glitch or fault in a power supply of a device).

### BACKGROUND

Computing devices often employ various techniques to protect data. As an example, data may be subjected to encryption and decryption techniques in a variety of scenarios, such as writing data to a storage device, reading data from a storage device, writing data to or reading data from a memory device, encrypting and decrypting blocks and/or volumes of data, encrypting and decrypting digital content, performing inline cryptographic operations, etc. Such encryption and decryption operations are often performed, at least in part, using a security information asset, such as a cryptographic key, a derived cryptographic key, etc. Certain scenarios exist in which attacks are performed in an attempt to obtain such security information assets. Accordingly, it is often advantageous to implement systems and techniques to protect such security information assets.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

Systems and techniques are described for providing a power supply glitch (e.g., fault) detector. In some aspects, a method of detecting faults is provided. The method includes: generating, by a first supply scale-down engine connected to a power supply of a device based on a lower voltage threshold, a first voltage within a threshold difference from a reference voltage; comparing, by a first comparator, the first voltage with the reference voltage; generating, by the first comparator based on determining the first voltage is less than the reference voltage, a low flag indicating detection of a fault in the power supply; generating, by a second supply scale-down engine connected to the power supply based on an upper voltage threshold, a second voltage within the threshold difference from the reference voltage; comparing, by a second comparator, the second voltage with the reference voltage; and generating, by the second comparator based on determining the second voltage is greater than the reference voltage, a high flag indicating detection of the fault in the power supply.

In some aspects, an apparatus for detecting faults is provided. The apparatus includes: a power supply; a first supply scale-down engine connected to the power supply, the first supply scale-down engine configured to generate, based on a lower voltage threshold, a first voltage within a threshold difference from a reference voltage; a first comparator configured to: compare the first voltage with the reference voltage; and generate, based on the first voltage being less than the reference voltage, a low flag indicating detection of a fault in the power supply; a second supply scale-down engine connected to the power supply, the second supply scale-down engine configured to generate, based on an upper voltage threshold, a second voltage within the threshold difference from the reference voltage; and a second comparator configured to: compare the second voltage with the reference voltage; and generate, based on the second voltage being is greater than the reference voltage, a high flag indicating detection of the fault in the power supply.

In some aspects, a non-transitory computer-readable medium having stored thereon instructions that, when executed by at least one processor, cause the at least one processor to generate, using a first supply scale-down engine connected to a power supply of a device based on a lower voltage threshold, a first voltage within a threshold difference from a reference voltage; compare, using a first comparator, the first voltage with the reference voltage; generate, by the first comparator based on determining the first voltage is less than the reference voltage, a low flag indicating detection of a fault in the power supply; generate, using a second supply scale-down engine connected to the power supply based on an upper voltage threshold, a second voltage within the threshold difference from the reference voltage; compare, using a second comparator, the second voltage with the reference voltage; and generate, by the second comparator based on determining the second voltage is greater than the reference voltage, a high flag indicating detection of the fault in the power supply.

In some aspects, an apparatus for detecting faults is provided. The apparatus includes: means for generating, based on a lower voltage threshold, a first voltage within a threshold difference from a reference voltage; means for comparing the first voltage with the reference voltage; means for generating, based on determining the first voltage is less than the reference voltage, a low flag indicating detection of a fault in the power supply; means for generating, based on an upper voltage threshold, a second voltage within the threshold difference from the reference voltage; means for comparing the second voltage with the reference voltage; and means for generating, based on determining the second voltage is greater than the reference voltage, a high flag indicating detection of the fault in the power supply.

In some aspects, one or more of the apparatuses described herein is, is a part of, or includes a mobile device (e.g., a mobile telephone or so-called “smart phone”, a tablet computer, or other type of mobile device), a wearable device, an extended reality (XR) device (e.g., a virtual reality (VR) device, an augmented reality (AR) device, or a mixed reality (MR) device), a personal computer, a laptop computer, a video server, a television (e.g., a network-connected television), a vehicle (or a computing device or system of a vehicle), or other device. In some aspects, the apparatus includes at least one camera for capturing one or more images or video frames. For example, the apparatus can include a camera (e.g., an RGB camera) or multiple cameras for capturing one or more images and/or one or more videos including video frames. In some aspects, the apparatus includes a display for displaying one or more images, videos, notifications, or other displayable data. In some aspects, the apparatus includes a transmitter configured to transmit one or more video frame and/or syntax data over a transmission medium to at least one device. In some aspects, the processor includes a neural processing unit (NPU), a central processing unit (CPU), a graphics processing unit (GPU), or other processing device or component.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

Some aspects include a device having a processor configured to perform one or more operations of any of the methods summarized above. Further aspects include processing devices for use in a device configured with processor-executable instructions to perform operations of any of the methods summarized above. Further aspects include a non-transitory processor-readable storage medium having stored thereon processor-executable instructions configured to cause a processor of a device to perform operations of any of the methods summarized above. Further aspects include a device having means for performing functions of any of the methods summarized above.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims. The foregoing, together with other features and aspects, will become more apparent upon referring to the following specification, claims, and accompanying drawings.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The preceding, together with other features and embodiments, will become more apparent upon referring to the following specification, claims, and accompanying drawings.

### BRIEF DESCRIPTION OF THE DRAWINGS

Illustrative aspects of the present application are described in detail below with reference to the following figures:

FIG. 1 is a block diagram illustrating side channel attacks on security information assets in a computing device, in accordance with some aspects of the disclosure.

FIG. 2 is a block diagram illustrating an example computing system including a function module, in accordance with some aspects of the disclosure.

FIG. 3 is a diagram illustrating a timeline including examples of supply fault injections occurring within a power supply voltage, in accordance with some aspects of the disclosure.

FIG. 4 is a diagram illustrating an example of a system for a high speed comparator based supply glitch detector, in accordance with some aspects of the disclosure.

FIG. 5 is a flow diagram illustrating a process for calibrating a reference voltage, in accordance with some aspects of the disclosure.

FIG. 6 is a flow diagram illustrating a process for calibrating a comparator up threshold, in accordance with some aspects of the disclosure.

FIG. 7 is a flow diagram illustrating a process for calibrating a comparator down threshold, in accordance with some aspects of the disclosure.

FIG. 8 is a flow diagram illustrating a process for adjusting a comparator up threshold and/or a comparator down threshold, in accordance with some aspects of the disclosure.

FIG. 9 is a flow diagram illustrating an example of a process for detecting a fault (e.g., a glitch) in a power supply, in accordance with some aspects of the disclosure.

FIG. 10 is a diagram illustrating an example of a system for implementing certain aspects described herein.

### DETAILED DESCRIPTION

Certain aspects of this disclosure are provided below for illustration purposes. Alternate aspects may be devised without departing from the scope of the disclosure. Additionally, well-known elements of the disclosure will not be described in detail or will be omitted so as not to obscure the relevant details of the disclosure. Some of the aspects described herein can be applied independently and some of them may be applied in combination as would be apparent to those of skill in the art. In the following description, for the purposes of explanation, specific details are set forth in order to provide a thorough understanding of aspects of the application. However, it will be apparent that various aspects may be practiced without these specific details. The figures and description are not intended to be restrictive.

The ensuing description provides example aspects only, and is not intended to limit the scope, applicability, or configuration of the disclosure. Rather, the ensuing description of the example aspects will provide those skilled in the art with an enabling description for implementing an example aspect. It should be understood that various changes may be made in the function and arrangement of elements without departing from the spirit and scope of the application as set forth in the appended claims.

The terms “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

As previously mentioned, computing devices often employ various techniques to protect data. As an example, data may be subjected to encryption and decryption techniques in a variety of scenarios, such as writing data to a storage device, reading data from a storage device, writing data to or reading data from a memory device, encrypting and decrypting blocks and/or volumes of data, encrypting and decrypting digital content, performing inline cryptographic operations, etc. Such encryption and decryption operations are often performed, at least in part, using a security information asset, such as a cryptographic key, a derived cryptographic key, etc.

Certain scenarios exist in which attacks are performed in an attempt to obtain such security information assets. For example, an attacker can attempt to reveal a security information asset and/or bypass a security check by using a fault attack, such as a laser fault injection (LFI) side channel attack. A fault attack, generally, is an attack on a physical electronic device (e.g., an integrated circuit chip) that involves stressing the device by an external means (e.g., voltage, light, laser, etc.) in order to generate errors in such a way that the errors lead to a security failure of the system (e.g., key recovery, false signature authorization, personal identification code recovery, balance increases, etc.). A successful fault attack on an integrated circuit (IC) chip requires the steps of fault injection followed by fault exploitation. Fault injection involves injecting a fault at an appropriate time during the security process. Fault injection is dependent upon the hardware of the device (e.g., the IC chip). Fault exploitation involves exploiting an erroneous result or an unexpected behavior of the device. Fault exploitation is dependent upon the software design and implementation.

Currently, secure processors (e.g., such as a processor within a trusted execution environment of a computing device, such as on an IC chip) require protection circuits that can monitor and track abrupt variations in voltages of sensitive power supplies (e.g., that power the secure processors) that are typically used for external fault injection attacks. Injected power supply variations can occur as fast as a system clock and, as such, a protection circuit needs to be able to output a corresponding flag (e.g., a high flag or a low flag) depending upon the detected direction of change in voltage within one clock period of the system clock.

A security system, including the secure processors, has a voltage range of interest for the power supply of the secure processors. A protection circuit is needed to determine whether a supply glitch (e.g., a fault, which may be caused by an attack) in the power supply voltage of the secure processors is above or below given threshold level voltages (e.g., above an upper voltage threshold or below a lower voltage threshold) to flag a high or low flag event, which can then be sent to a secure subsystem for further processing (e.g., to shut down processing of the secure processors to protect the device).

A typical existing solution to monitor a power supply voltage of secure processors uses a high-speed analog-to-digital converter (ADC) to convert the power supply voltage to a digital code. The solution compares the digital code to digital references to determine whether to flag that an upper voltage threshold has been exceeded or a lower voltage threshold has not been met. A high-speed ADC consumes a large area on the IC chip of the device and has a significant power dissipation. This solution requires high amount of area on a chip and a large amount of power consumption.

As such, improved systems and techniques that provide a protection circuit that can handle power supply variations across a wide power supply voltage variation range, while maintaining a small area on an IC chip and a low power consumption, can be beneficial.

In one or more aspects of the present disclosure, systems, apparatuses, methods (also referred to as processes), and computer-readable media (collectively referred to herein as “systems and techniques”) are described herein that provide solutions for a high speed comparator-based supply glitch (e.g., fault) detector.

Various aspects relate generally to a power supply glitch (e.g., fault) detector. Some aspects more specifically relate to systems and techniques that provide solutions for a protection circuit that, instead of employing an ADC like existing solutions, use an internally generated programmable reference voltage, two comparators, and two supply scale-down circuits that generate an upper voltage threshold and a lower voltage threshold. The protection circuit is connected directly to the power supply of interest, and monitors variations in voltage of the power supply at every clock cycle. The design of the protection circuit requires a smaller amount of area on the IC chip and consumes much lower power, as compared to existing ADC solutions. The protection circuit, which is a comparator-based solution, is able to minimize both the power and chip area consumption without the need for fully digitizing the tracked power supply voltage.

In one or more examples, the systems and techniques tune an internally generated voltage to generate a reference voltage for the comparators. In some examples, the upper and lower thresholds can be adjusted by using a threshold adjustment calibration sequence. In one or more examples, the upper and lower thresholds can be adjusted using a programmable circuit to generate voltages that are close to the tuned reference voltage, depending upon the user equipment. After the calibration has been completed, the comparators can track (e.g., monitor) the power supply voltage at every clock cycle, and can output high and low flags when the power supply voltage has been determined to be above the upper voltage threshold or below the lower voltage threshold.

In one or more aspects, during operation of a method of detecting faults, a first supply scale-down engine (e.g., a down threshold programmability engine), connected to a power supply (e.g., sensed supply) of a device, can generate, based on a lower voltage threshold (vth_lower), a first voltage (e.g., a voltage on a down voltage threshold line) close to (e.g., within a threshold difference from) a reference voltage (Vref). A first comparator (e.g., a low flag comparator) can compare the first voltage with the reference voltage. The first comparator can generate, based on determining the first voltage is less than the reference voltage, a low flag indicating detection of a fault in the power supply. For example, the threshold difference can correspond to a comparator sensitivity (e.g., a sensitivity of the first comparator), which is a measure of how small of a difference between the comparator inputs the can comparator detect and react to. An illustrative example of a threshold difference is 1 millivolt (1 mV). For instance, for a comparator sensitivity of 1 mV, if the difference between the positive and negative terminals of the comparator inputs are 1 mV or more, the comparator can provide a new decision (high or low). In such an example, if the difference between the positive and negative terminals of the comparator inputs are less than 1 mV, the comparator will maintain the current decision (low or high).

A second supply scale-down engine (e.g., an up threshold programmability engine), connected to the power supply (e.g., the sensed supply), can generate, based on an upper voltage threshold (vth_upper), a second voltage (e.g., a voltage on an up voltage threshold line) close to (e.g., within the threshold difference from) the reference voltage (Vref). A second comparator (e.g., a high flag comparator) can compare the second voltage with the reference voltage. The second comparator can generate, based on determining the second voltage is greater than the reference voltage, a high flag indicating detection of the fault in the power supply.

In one or more examples, a reference programmability engine of the device can generate the reference voltage. In some examples, a voltage at a reference voltage node can be measured, during performing a code sweep by the reference programmability engine, to obtain a measured reference voltage. A corresponding code for the reference programmability engine can be determined, based on determining the measured reference voltage is close to (e.g., within the threshold difference from) a target reference voltage (e.g., 0.1 volts). The code can be fused for the reference programmability engine.

In some examples, the reference voltage (e.g., 0.1 volts) can be less than the lower voltage threshold (e.g., 0.2 volts) and the upper voltage threshold (e.g., 0.9 volts). In one or more examples, the first comparator can monitor the first voltage (e.g., a voltage on a down voltage threshold line) at every clock cycle of a system clock of the device. In some examples, the second comparator can monitor the second voltage (e.g., a voltage on an up voltage threshold line) at every clock cycle of the system clock.

In one or more examples, the power supply (e.g., sensed supply) can be set to an upper threshold target voltage (e.g., 0.8 volts). The second supply scale-down engine can perform a code sweep. A code corresponding to the second supply scale-down engine can be determined based on determining the second comparator generates the high flag during the code sweep, resulting in output of the second supply scale-down engine close to the reference voltage. The code can be fused for the second supply scale-down engine. In some examples, the code sweep can be from a first voltage (e.g., zero volts) to a second voltage (e.g., a full-scale value, such as a full-scale voltage) higher than the first voltage. In some examples, an adjusted code for the second supply scale-down engine can be determined, based on determining the upper threshold target voltage (e.g., 0.8 volts) is not close to (e.g., within the threshold difference from) the upper voltage threshold (e.g., 0.9 volts), based on a ratio of the upper threshold target voltage (e.g., 0.8 volts) over the upper voltage threshold (e.g., 0.9 volts).

In some one or more examples, the power supply (e.g., sensed supply) can be set to a lower threshold target voltage (e.g., 0.4 volts). The first supply scale-down engine can perform a code sweep. A code corresponding to the first supply scale-down engine can be determined based on determining the first comparator generates the low flag during the code sweep. The code can be fused for the first supply scale-down engine. In one or more examples, the code sweep can be from a first voltage (e.g., a full-scale value, such as a full-scale voltage) to a second voltage (e.g., zero volts) lower than the first voltage. In one or more examples, an adjusted code for the first supply scale-down engine can be determined, based on determining the lower threshold target voltage (e.g., 0.4 volts) is not close to (e.g., within the threshold difference from) the lower voltage threshold (e.g., 0.2 volts), based on a ratio of the lower threshold target voltage (e.g., 0.4 volts) over the lower voltage threshold (e.g., 0.2 volts).

Particular aspects of the subject matter described in this disclosure can be implemented to realize one or more of the following potential advantages. In one or more examples, the systems and techniques can provide a benefit of providing a wide power supply range of operation. In some examples, the systems and techniques can provide the benefits of allowing for a low current consumption and a low area on an integrated circuit (IC) chip of a device, as compared to existing ADC-based architectures. In one or more examples, the systems and techniques can provide the benefits of being able to directly connect to the power supply of interest, and using an internally-generated reference voltage. In some examples, the systems and techniques can provide the benefit of utilizing a simple one-time calibration to cancel inherent offsets in the comparators within the system. In one or more examples, the systems and techniques can provide the benefit of only requiring a target system to set an upper voltage threshold and a lower voltage threshold for the glitch (e.g., fault) detection. In some examples, the systems and techniques can provide the benefit of providing upper and low volage thresholds that may be outside of the safe-operating region of IC chip (e.g., the silicon) of the device. In one or more examples, the systems and techniques can provide the benefit of being capable to detect sharp glitches (e.g., faults) that occur as fast as the system clock.

Additional aspects of the present disclosure are described in more detail below.

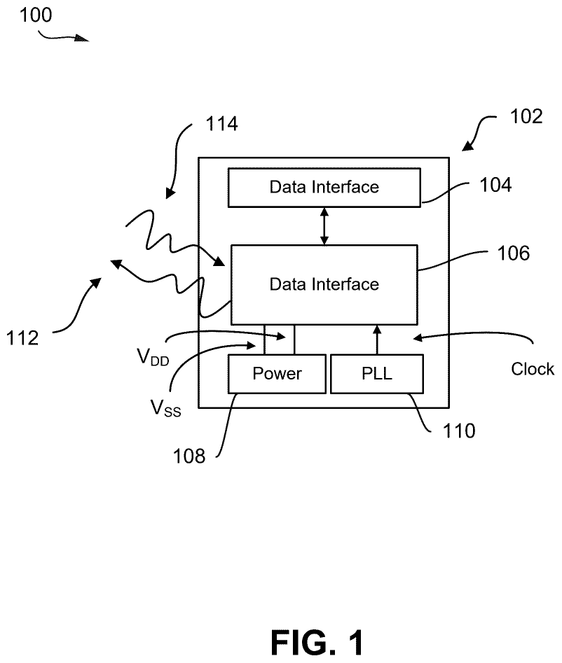

Various aspects of the systems and techniques described herein will be discussed below with respect to the figures. In some cases, security information assets can be compromised by side channel attacks. FIG. 1 is a block diagram 100 illustrating side channel attacks on security information assets in a computing device (e.g., cryptographic device 102). In some examples, cryptographic device 102 may obtain a security information asset (e.g., a cryptographic key). For example, the security information asset may be obtained from a security information asset storage when a computing device boots, reboots, and/or updates to be used for various security operations (e.g., encryption and/or decryption operations, key derivation operations, other steps or transformations performed using a security information asset, etc.). In some cases, the security information asset may be stored on the security information asset storage in a masked form or an unmasked form. In some cases, the cryptographic device 102 can communicate with the secure information asset storage over a data interface 104.

In some examples, a secure execution environment is any portion of a computing device that is a secure area of the computing device. Examples of secure execution environments include, but are not limited to, trusted management environments, trusted execution environments, trust zones, trusted platform modules, secure components, secure elements, and/or any combination thereof.

In some aspects, security components of a computing device may require a security information asset (e.g., a secret key) to perform one or more security operations (e.g., encrypting and/or decrypting data, generating derivative cryptographic keys, any other steps and or transformations performed using a security information asset, etc.). For example, the security components can include the cryptographic processor 106 of FIG. 1. As illustrated, the data interface 104 can be communicatively coupled to the cryptographic processor 106 and data can be exchanged between data interface 104 and cryptographic processor 106. For example, the exchanged data can include, without limitation, plain text, cypher text, secret keys, security information assets, and/or any combination thereof. As illustrated in FIG. 1, the cryptographic device 102 can include power components 108 that can generate reference voltages (e.g., V_{DD}, V_{SS}) for powering the cryptographic processor 106. In some examples, the cryptographic device 102 can include a phase locked loop (PLL) 110 for providing a clock signal to the cryptographic processor 106.

In some cases, use of security information assets may allow an attacker to use various techniques to obtain all or any portion of a security information asset, which may potentially compromise the security of a computing device. As an example, an attacker may perform a side channel attack by using a measurement device (e.g., an oscilloscope) to measure any number of characteristics of a computing device as it operates (e.g., voltages, power, electromagnetic outputs, timing information, sound, temperature, etc.). In some cases, side channel attacks that include measurements of emitted signals from the 102 can be referred to as a passive attack 112. In some cases, an attacker can utilize a machine learning (ML) model (e.g., a deep learning neural network) to aid in a side channel attack. In some examples, an attacker may utilize an active attack 114 for performing a side channel attack. For example, an attacker may employ fault injection techniques. In one illustrative example, a laser fault injection (LFI) can be utilized in a side channel attack on the cryptographic device 102.

In some cases, an attacker using a side channel attack or a fault injection attack as a cryptographic key is being transmitted and/or received (e.g., when obtained from a security information asset storage device at boot time, when obtained from a different storage device, when provided to security components for use in performing security operations, used to derive other cryptographic keys, etc.) may be able to deduce the cryptographic key, and thus be able to use the key to decrypt data on the computing device and/or encrypt potentially malicious data using the correct key, which may then be used by the computing device. In some cases, an attacker using a side channel attack can induce a single event upset (SEU) such as a bit-flip. In some cases, a side channel attack can be used to reveal a secret key, corrupt code execution within the cryptographic device 102, bypass secure boot, and/or any combination thereof.

In some examples, changes in the substrate potential induced by the LFI can be detected by monitoring the substrate potential with on-chip monitoring at distributed substrate potential measurement sensors distributed throughout the substrate of a cryptographic device (e.g., cryptographic device 102 of FIG. 1). In some cases, the substrate potential measurement sensing technique can be referred to as a substrate potential bounce (SPB) monitor. In some cases, the addition of substrate potential measurement sensors throughout a cryptographic device can be costly due to area consumed by measurement pads and/or specialized measurement circuitry. For example, a SPB monitor may utilize specialized measurement circuitry including analog buffers and/or voltage comparators to detect the SPB. In some cases, the specialized measurement circuitry may require trimming and/or threshold level tuning to properly detect an LFI attack. In some aspects, an SPB monitor may provide only an indirect measurement of an LFI by measuring then effect of the LFI on the power distribution networks (e.g., electrical traces for distributing V_{DD}, V_{SS}) of a cryptographic device. In some cases, a SPB monitor may also be susceptible to latch-up issues that may require cycling the power supply of the cryptographic device off and back on to resolve.

In some implementations, a bulk built-in current sensor (BBICS) can be used to detect changes in substrate potential resulting from an LFI attack on a cryptographic device (e.g., cryptographic device 102 of FIG. 1). In some cases, the BBICS sensor can be implemented by providing an isolated bulk terminal and back-end circuitry to detect bulk voltage spikes that can result from abnormal current pulses. In some cases, a dedicated bulk voltage distribution network with a lower resistance may be used to distribute the bulk voltage throughout a cryptographic device. In some examples, the positive and negative voltage rails (e.g., V_{DD}, V_{SS}) may each also have a dedicated voltage distribution network with a low resistance. In some cases, adding the dedicated bulk voltage distribution network can add cost and/or complexity to the design of a cryptographic device.

The systems and techniques described herein may be implemented by any type of system or device. One illustrative example of a system that can be used to implement the systems and techniques described herein is a computing device, or a system or component of the computing device.

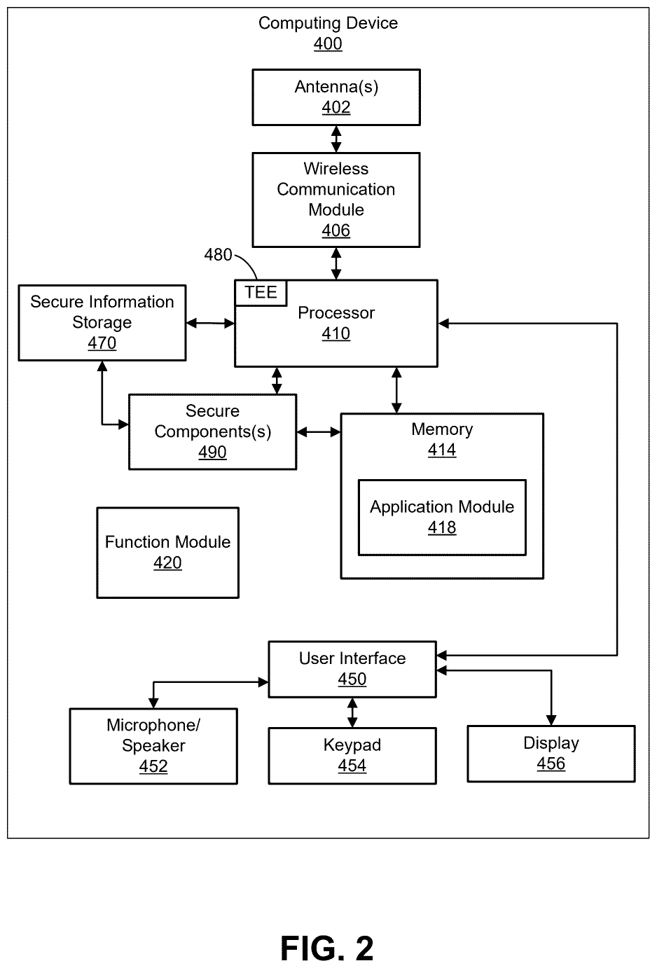

According to various examples, FIG. 2 is a diagram illustrating an example computing device 200 that may implement the systems and techniques described herein. The computing device 200 may include, but is not limited to, any of the following: one or more processors (e.g., components that include integrated circuitry, memory, input and output device(s) (not shown), non-volatile storage hardware, one or more physical interfaces, any number of other hardware components (not shown), and/or any combination thereof. Examples of computing devices include, but are not limited to, a mobile device (e.g., laptop computer, smart phone, personal digital assistant, tablet computer, automobile computing system, and/or any other mobile computing device), an Internet of Things (IoT) device, a server (e.g., a blade-server in a blade-server chassis, a rack server in a rack, etc.), a desktop computer, a storage device (e.g., a disk drive array, a fiber channel storage device, an Internet Small Computer Systems Interface (iSCSI) storage device, a tape storage device, a flash storage array, a network attached storage device, etc.), a network device (e.g., switch, router, multi-layer switch, etc.), a wearable device (e.g., a network-connected watch or smartwatch, or other wearable device), a robotic device, a smart television, a smart appliance, an extended reality (XR) device (e.g., augmented reality (AR), virtual reality (VR), etc.), any device that includes one or more System on Chips (SoCs), and/or any other type of computing device with the aforementioned requirements. In one or more examples, any or all of the aforementioned examples may be combined to create a system of such devices, which may collectively be referred to as a computing device. Other types of computing devices may be used without departing from the scope of examples described herein.

As illustrated, the computing device 200 may include one or more antennas 202, one or more wireless communication modules 206, a processor 210, memory 214, application module 218, a function module 220, user interface 250, microphone/speaker 252, keypad 254, display 256, secure information storage 270, trusted execution environment 280, and secure components 290.

As shown, the computing device 200 may include one or more wireless communication modules 206 that may be connected to one or more antennas 202. The one or more wireless communication modules 206 comprise suitable devices, circuits, hardware, and/or software for communicating with and/or detecting signals to/from an access point, a network, a base station, and/or directly with other wireless devices within a network.

In some implementations, the one or more wireless communication modules 206 may comprise a CDMA communication system suitable for communicating with a CDMA network of wireless base stations. In some implementations, the wireless communication system may comprise other types of cellular telephony networks, such as, for example, TDMA, GSM, WCDMA, LTE, NR, and the like. Additionally, any other type of wireless networking technologies may be used, including, for example, WiMax (602.16), Wi-Fi (602.11), and the like.

The processor(s) (also referred to as a controller) 210 may be connected to the one or more wireless communication modules 206. The processor 210 may include one or more microprocessors, microcontrollers, and/or digital signal processors that provide processing functions, as well as other calculation and control functionality. The processor 210 may be coupled to storage media (e.g., memory) 214 for storing data and software instructions for executing programmed functionality within the mobile device. The memory 214 may be on-board the processor 210 (e.g., within the same IC package), and/or the memory may be external memory to the processor and functionally coupled over a data bus.

A number of software engines and data tables may reside in memory 214 and may be utilized by the processor 210 in order to manage communications, perform positioning determination functionality, and/or perform device control functionality. In some cases, the memory 214 may include an application module 218. It is to be noted that the functionality of the modules and/or data structures may be combined, separated, and/or be structured in different ways depending upon the implementation of the computing device 200.

The application module 218 may include a process running on the processor 210 of the computing device 200, which may request data from one of the other modules of the computing device 200. Applications typically run within an upper layer of the software architectures and may be implemented in a rich execution environment of the computing device 200, and may include indoor navigation applications, shopping applications, financial services applications, social media applications, location aware service applications, etc.

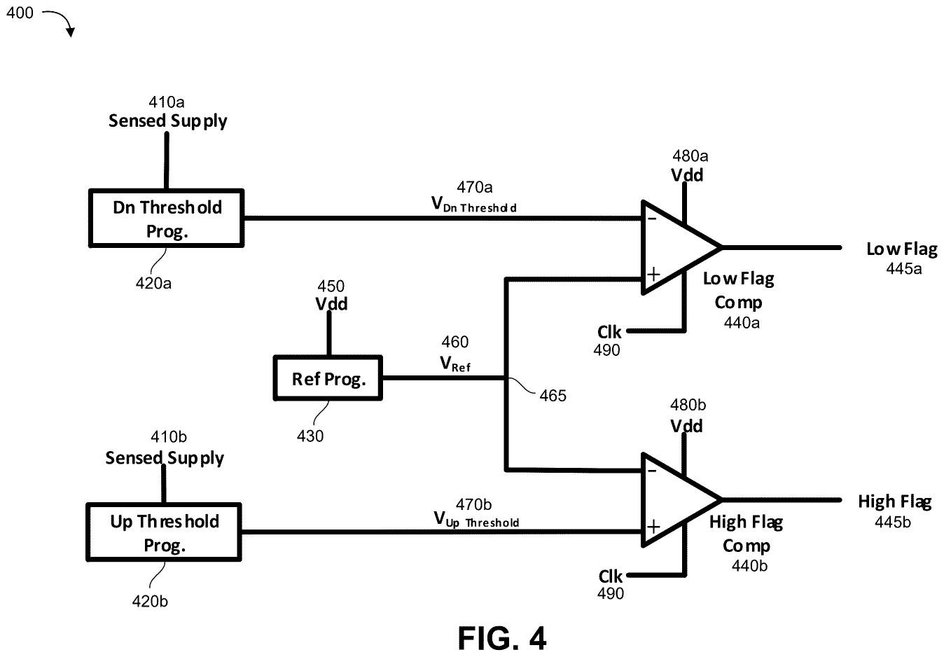

As illustrated, the computing device 200 can include a function module 220. In some cases, the function module 220 can be incorporated with one or more of the processor 210, secure information storage 270, trusted execution environment 280, or secure components 290. In some cases, the function module 220 can include a high speed comparator based supply glitch detector, such as the system 400 (e.g., a protection circuit) for a high speed comparator based supply glitch detector of FIG. 4.

In FIG. 2, in some examples, the computing device 200 includes the secure information storage 270. In some examples, the secure information storage 270 can be any storage device configured to store security information assets (e.g., cryptographic keys, metadata, etc.). For instance, the secure information storage 270 is where security information assets are stored and initially obtained from when needed for use on a computing device (e.g., for encryption and/or decryption of data). In some cases, the secure information storage 270 can include a key store or a key table. Examples of secure information storage 270 include, but are not limited to, various types of read-only memory, one-time programmable memory devices (e.g., one time programmable fuses or other types of one time programmable memory devices), non-volatile memory, etc. The secure information storage 270 may be operatively connected to the trusted execution environment 280 and/or the secure components 290. Although FIG. 2 shows the computing device 200 as including a single secure information storage 270, the computing device 200 may include any number of secure information storages without departing from the scope of examples described herein.

The processor 210 may include a trusted execution environment 280. The trusted execution environment 280 may also be referred to as a trusted management environment, trust zones, trusted platform modules, or the like. The trusted execution environment 280 can be implemented as a secure area of the processor 210 that can be used to process and store sensitive data in an environment that is segregated from the rich execution environment in which the operating system and/or applications (such as those of the application module 218) may be executed. The trusted execution environment 280 can be configured to execute secure applications (also referred to as trusted applications) that provide end-to-end security for sensitive data by enforcing confidentiality, integrity, and protection of the sensitive data stored therein. The trusted execution environment 280 can be used to store encryption keys, access tokens, and other sensitive data.

The computing device 200 may include one or more secure components 290. In some cases, the secure components 290 can be referred to as trusted components, secure elements, trusted elements, or the like. The computing device 200 may include the secure components 290 in addition to or instead of the trusted execution environment 280. The secure components 290 can comprise autonomous and tamper-resistant hardware that can be used to execute secure applications and the confidential data associated with such applications. The secure components 290 can be used to store encryption keys, access tokens, and other sensitive data. The secure components 290 can comprise a Near Field Communication (NFC) tag, a Subscriber Identity Module (SIM) card, or other type of hardware device that can be used to securely store data. The secure components 290 can be integrated with the hardware of the computing device 200 in a permanent or semi-permanent fashion or may, in some implementations, be a removable component of the computing device 200 that can be used to securely store data and/or provide a secure execution environment for applications.

Examples of secure applications that may be performed by the computing device 200, processor 210, secure information storage 270, trusted execution environment 280, secure components 290, and/or any combination thereof include, but are not limited to, encrypting data, decrypting data, key derivation, performing data integrity verification, and performing authenticated encryption and decryption. In some examples, the computing device 200 and/or portions thereof can be configured to perform the various cryptographic service types by being configured to execute one or more cryptographic algorithms. As an example, to perform encryption and decryption, one or more components (e.g., secure information storage 270, trusted execution environment 280, secure components 290) of the computing device 200 may be configured to execute one or more of the Advanced Encryption Standard XOR-encrypt-XOR Tweakable Block Ciphertext Stealing (AES-XTS) algorithm, the AES-Cipher Block Chaining (AES-CBC) algorithm, the AES-Electronic Codebook (AES-EBC) algorithm, the Encrypted Salt-Sector Initialization Vector-AES-CBC (ESSIV-AES-CBC) algorithm, etc., including any variants of such algorithms (e.g., 128 bits, 192 bits, 256 bits, etc.). As another example, to perform integrity verification, one or more components of the computing device 200 may be configured to execute a hash algorithm such as, for example, the one or more members of the SHA family of hash algorithms. As another example, to perform authenticated encryption, one or more components of the computing device 200 may be configured to perform the AES-Galois/Counter Mode (GCM) algorithm. In some aspects, one or more components of the computing device 200 may be configured to execute any other cryptographic algorithms without departing from the scope of examples described herein.

The computing device 200 may further include a user interface 250 providing suitable interface systems, such as a microphone/speaker 252, a keypad 254, and/or a display 256 that allows user interaction with the computing device 200. The microphone/speaker 252 can provide for voice communication services (e.g., using the one or more wireless communication modules 206). The keypad 254 may comprise suitable buttons for user input. The display 256 may include a suitable display, such as, for example, a backlit LCD display, and may further include a touch screen display for additional user input modes.

While FIG. 2 shows a certain number of components in a particular configuration, one of ordinary skill in the art will appreciate that the computing device 200 may include more components or fewer components, and/or components arranged in any number of alternate configurations without departing from the scope of examples described herein. Additionally, although not shown in FIG. 2, one of ordinary skill in the art will appreciate that the computing device 200 may execute any amount or type of software or firmware (e.g., bootloaders, operating systems, hypervisors, virtual machines, computer applications, mobile device apps, etc.). Accordingly, examples disclosed herein should not be limited to the configuration of components shown in FIG. 2. The components shown in FIG. 2 may or may not be discrete components. In some aspects, one or more of the components can be combined into different hardware elements, implemented in software, and/or otherwise implemented using software and/or hardware. As used herein, the term device may be a discrete component or apparatus, or may not be a discrete component. In some aspects, other devices can exist within, be part of, and/or utilize the same hardware components as a device.

As previously mentioned, currently, secure processors (e.g., such as a processor within a trusted execution environment, such as trusted execution environment 280, of a computing device, such as computing device 200) need protection circuits that can monitor and detect abrupt variations in voltages of power supplies (e.g., of the secure processors) that are often targeted by external fault injection attacks. Injected power supply variations can occur as fast as a system clock and, thus, a protection circuit needs to be able to detect an abrupt variation (e.g., which exceeds or is below an upper or lower voltage threshold, respectively) within one clock period of the system clock.

Currently, typical existing solutions for monitoring a power supply voltage of secure processors utilize an ADC to convert the power supply voltage to a digital code, which is then compared with digital reference codes to determine whether there is a variation in voltage that is above an upper voltage threshold or is below a lower voltage threshold. However, these existing solutions consume a large amount of IC chip area and a large amount of power. Therefore, improved systems and techniques that provide a protection circuit that can handle power supply variations across a wide power supply voltage variation range, while maintaining a small area on an IC chip and a low power consumption, can be useful.

In one or more aspects, the systems and techniques provide solutions for a high speed comparator-based supply glitch (e.g., fault) detector. In one or more examples, systems and techniques provide a protection circuit that, instead of employing an ADC as existing solutions, employ an internally generated programmable reference voltage, two comparators, and two supply scale-down circuits that generate an upper voltage threshold and a lower voltage threshold. The protection circuit design requires a smaller amount of area on the IC chip and consumes much lower power, as compared to the existing ADC solutions.

The disclosed protection circuit can monitor and track abrupt variations in voltages of power supplies of secure processors. The protection circuit can identify whether a supply glitch (e.g., a fault, which may be caused by an attack) in the power supply voltage is above an upper voltage threshold or below a lower voltage threshold. After identifying that the supply voltage has exceeded the upper voltage threshold or the lower voltage threshold, the protection circuit can output a high flag or a low flag, respectively. The outputted flag (e.g., either high flag or low flag) can be sent to a secure subsystem for further processing, such as for the secure subsystem to shut down processing of the secure processors that may be experiencing a fault attack.

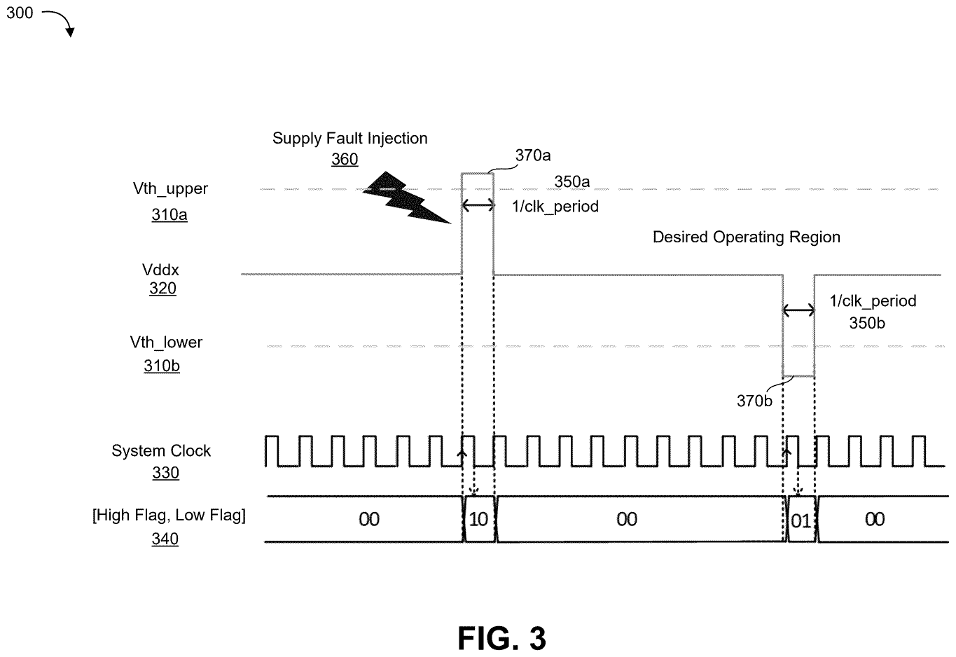

FIG. 3 shows an example fault injections in a power supply voltage (e.g., supply fault injections). In particular, FIG. 3 is a diagram illustrating a timeline 300 including examples of power supply fault injections 360 occurring within a power supply voltage (Vddx) 320. In FIG. 3, the horizontal axis of the timeline 300 represents time. The timeline 300 is shown to include the power supply voltage (Vddx) 320 over time, an upper voltage threshold (vth_upper) 310a, a lower voltage threshold (vth_lower) 310b, a system clock 330 with a clock period, and flag codes 340 (e.g., indicating a high flag or a low flag). The flag code 340 illustrated in FIG. 3 corresponds to an indication of a high flag and a low flag, where a state of the high flag is indicated by the most significant bit (MSB) of the flag code 340 and a state of the low flag is indicated by the least significant bit (LSB) of the flag code 340. For example, a value of the flag code 340 equal to 10 indicates that high flag is active (based on the MSB being equal to 1) and indicates the low flag is inactive (based on the LSB being equal to 0), while a value of the flag code 340 equal to 01 indicates that low flag is active (based on the LSB being equal to 1) and indicates the high flag is inactive (based on the MSB being equal to 0).

As shown in FIG. 3, the power supply voltage (Vddx) 320 increases, over a duration equal to one over the clock period 350 a (e.g., 1/clk_period) of the system clock 330, to a voltage level 370a that is above (e.g., exceeds) the upper voltage threshold (vth_upper) 310a. A protection circuit (e.g., protection circuit 400 of FIG. 4) of the systems and techniques, which is monitoring the power supply voltage (Vddx) 320, can identify this voltage level 370a as being greater than the upper voltage threshold (vth_upper) 310a. Upon determining that the voltage level 370a is greater than the upper voltage threshold (vth_upper) 310a, the protection circuit can output a flag code 340 that is equal to 10, indicating that the high flag is active (based on the MSB being equal to 1) and indicating the low flag is inactive (based on the LSB being equal to 0).

Also shown in FIG. 3, the power supply voltage (Vddx) 320 decreases, over a duration equal to one over the clock period 350b of the system clock 330, to a voltage level 370b that is below (e.g., lower than) the lower voltage threshold (vth_lower) 310b. The protection circuit (e.g., protection circuit 400 of FIG. 4) of the systems and techniques, which is monitoring the power supply voltage (Vddx) 320, can identify this voltage level 370b as being less than the lower voltage threshold (vth_lower) 310b. Upon determining that the voltage level 370b is lower than the lower voltage threshold (vth_lower) 310b, the protection circuit can output a flag code 340 that is equal to 01, indicating that the high flag is inactive (based on the MSB being equal to 0) and the low flag is active (based on the LSB being equal to 1).

FIG. 4 shows an example of a protection circuit that may be employed by the systems and techniques. In particular, FIG. 4 is a diagram illustrating an example of a system 400 (e.g., a protection circuit) for a high speed comparator based supply glitch detector. In FIG. 4, the system 400 is shown to include a low flag comparator (comp) 440a (e.g., a first comparator), a high flag comparator 440b (e.g., a second comparator), a down (dn) threshold programmability (prog.) engine 420a (e.g., a first supply scale-down engine), an up threshold programmability engine 420b (e.g., a second supply scale-down engine), and a reference (ref) programmability engine 430. In one or more examples, an engine may be in the form of a circuit.

The low flag comparator 440a is shown to be connected to a clock (clk) 490 and a voltage source (Vdd) 480a. Similarly, the high flag comparator 440b is shown to be connected to the clock 490 490and a voltage source (Vdd) 480b (e.g., which may be the same as or different from voltage source 480a). The reference programmability engine 430 is shown to be connected to a voltage source (Vdd) 450 (e.g., which may be the same or different than the voltage source 480a and/or the voltage source 480b).

A sensed supply 410a (e.g., supplying the power supply voltage (Vddx) to be monitored, such as power supply voltage (Vddx) 320 of FIG. 3) is shown to be connected to the down (dn) threshold programmability engine 420a. Similarly, a sensed supply 410b (e.g., which is the same as the sensed supply 410a, such as power supply voltage (Vddx) 320 of FIG. 3) is shown to be connected to the up threshold programmability engine 420b. The down (dn) threshold programmability engine 420a is shown to be connected to a negative node of the low flag comparator via a down voltage (V_{DN}) threshold line 470a. Similarly, the up threshold programmability engine 420b is shown to be connected to a positive node of the high flag comparator 440b via an up voltage (V_{UP}) threshold line 470b.

Prior to the operation of the system 400 (e.g., protection circuit), a lower voltage threshold (vth_lower) (e.g., the lower voltage threshold (vth_lower) 310b of FIG. 3) and an upper voltage threshold (vth_upper) (e.g., the upper voltage threshold (vth_upper) 310a of FIG. 3) should be chosen. In one or more examples, the lower voltage threshold (vth_lower) and the upper voltage threshold (vth_upper) may be selected by a customer of the system 400 or of a device (e.g., mobile device, such as a mobile phone) including the system 400.

After the lower voltage threshold (vth_lower), such as 0.2 volts, and the upper voltage threshold (vth_upper), such as 0.9 volts, have been selected, a reference voltage (Vref) 460 (e.g., 0.1 volts) may be selected (e.g., by the manufacturer of the system 400 and/or the device including the system 400) based on the selected lower voltage threshold (vth_lower) and the upper voltage threshold (vth_upper). In one or more examples, the reference voltage (Vref) 460, such as 0.1 volts, should be selected to be lower than both the lower voltage threshold (vth_lower) and the upper voltage threshold (vth_upper). In one or more examples, the reference programmability engine 430 can generate (e.g., internally generate within the system 400) the selected reference voltage (Vref) 460, which can be measured at reference node 465 of the system 400. The reference node 465 is shown to be connected to the positive node of the low flag comparator 440a and connected to the negative node of the high flag comparator 440b.

In one or more examples, the positive node and the negative node of the low flag comparator 440a need to have voltages such that the voltage levels are close to (e.g., within a threshold difference from) or equal to each other for the low flag comparator 440a to perform an accurate comparison of the voltages. Similarly, the positive node and the negative node of the high flag comparator 440b need to have voltages such that the voltage levels are close to or equal to each other for the high flag comparator 440b to perform an accurate comparison of the voltages.

To ensure that the voltages on the positive node and the negative node on the low flag comparator 440a have voltage levels that are close to (e.g., within a threshold difference from) or equal to each other, the down (dn) threshold programmability engine 420a can scale down the voltage, such as 0.2 volts, of the selected lower voltage threshold (vth_lower) such that the down voltage (V_{DN}) threshold line 470a has a voltage level that is close to or equal to the reference voltage (Vref) 460, such as 0.1 volts. Similarly, to ensure that the voltages on the positive node and the negative node on the high flag comparator 440b have voltage levels that are close to or equal to each other, the up threshold programmability engine 420b can scale down the voltage, such as 0.9 volts, of the selected upper voltage threshold (vth_upper) such that the up voltage (V_{UP}) threshold line 470b has a voltage level that is close to or equal to the reference voltage (Vref) 460, such as 0.1 volts.

After the voltages have been scaled down, the system 400 of FIG. 4 can operate to perform monitoring (e.g., at ever clock cycle of the clock 490) of the sensed supply 410a, 410b (e.g., the power supply voltage (Vddx) 320 of FIG. 3) for a supply fault injection. During operation of the system 400, if the positive node of the low flag comparator 440a experiences a higher voltage level than the negative node of the low flag comparator 440a, the low flag comparator 440a will output a low flag 445a, indicating that the sensed supply 410a (e.g., the power supply voltage (Vddx) 320 of FIG. 3) is lower than the lower voltage threshold (vth_lower), such as 0.2 volts, and as such may be experiencing a supply fault injection. If the positive node of the high flag comparator 440b experiences a higher voltage level than the negative node of the high flag comparator 440b, the high flag comparator 440b will output a high flag 445b, indicating that the sensed supply 410b (e.g., the power supply voltage (Vddx) 320 of FIG. 3) is higher than the upper voltage threshold (vth_upper), such as 0.9 volts, and as such may be experiencing a supply fault injection.

After a low flag 445a or a high flag 445b has been outputted by the system 400, the low flag 445a or the high flag 445b can be sent to a secure subsystem for further processing. In one or more examples, upon receiving a low flag 445a or a high flag 445b, the secure subsystem may shut down processing of the secure processors (e.g., powered by the sensed supply 410a, 410b) to protect the device (e.g., IC chip) from an attack of a supply fault injection.

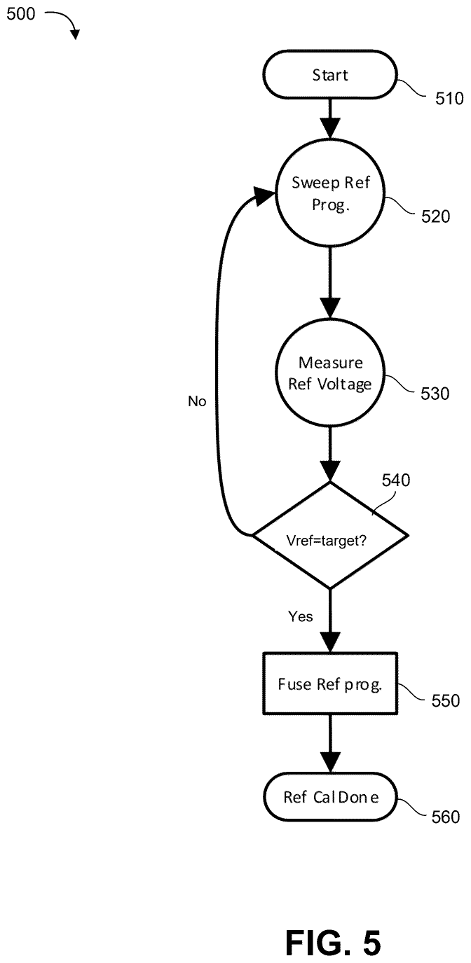

In one or more aspects, prior to operation of the system 400 (e.g., as described in the description of FIG. 4), a one-time calibration procedure can be performed on the system 400 to calibrate the reference voltage (Vref) 460, and to calibrate the upper voltage threshold (vth_upper) and the lower voltage threshold (vth_lower) to cancel inherent offsets within the two comparators (e.g., the low flag comparator 440a and the high flag comparator 440b) of the system 400. FIGS. 5, 6, 7, and 8 show processes that can be performed (e.g., in the order of the figures) for performing the one-time calibration procedure.

FIG. 5 is a flow diagram illustrating a process 500 for calibrating a reference voltage, such as reference voltage (Vref) 460 of FIG. 4. During operation of the process 500 of FIG. 5, at block 510, the process 500 can start. After the process 500 starts, a probe of test equipment (e.g., automatic test equipment (ATE)) can probe the reference node 465 to measure the reference voltage (Vref) 460. At block 520, the reference programmability engine 430 can output a voltage and sweep the output voltage from zero volts to the full scale of volts. While the reference programmability engine 430 is sweeping the output voltage, at block 530, the probe can measure the reference voltage 460 at the reference node 465. At decision block 540, one or more processors (or a tester) can determine whether the reference voltage 460 measured at the reference node 465 is close to (e.g., within a threshold difference from) a target reference voltage (e.g., set by the manufacturer of the device), such as 0.1 volts. If the one or more processors determine that the reference voltage 460 measured at the reference node 465 is not equal to a target reference voltage, the process 500 can proceed back to block 520.

However, if the one or more processors determine that the reference voltage 460 measured at the reference node 465 is close to (e.g., within a threshold difference from) a target reference voltage, at block 550, a code (e.g., a bit code, such as a seven bit code) of the reference programmability engine 430, which corresponds to the output voltage of the reference programmability engine 430 to make the reference node 465 close to (e.g., within a threshold difference from) a target reference voltage (e.g., 0.1 volts), can be fused for the reference programmability engine 430. After the code of the reference programmability engine 430 is fused, at block 560, the reference voltage calibration is done.

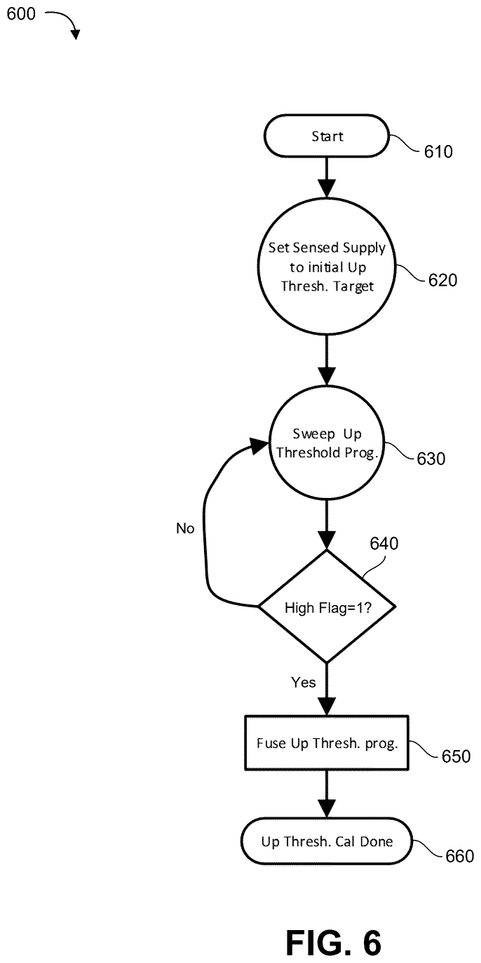

FIG. 6 is a flow diagram illustrating a process 600 for calibrating a comparator up threshold (e.g., the upper voltage threshold (vth_upper)). The upper voltage threshold (vth_upper), such as 0.9 volts, may be set by the customer of the device. However, the desired upper voltage threshold (vth_upper), such as 0.9 volts, may be too high for accurate testing. For this reason, an alternative voltage level (e.g., an upper threshold voltage target), such as 0.8 volts, which is close to the desired upper voltage threshold (vth_upper), may be used for testing purposes.

During operation of the process 600 of FIG. 6, at block 610, the process 600 can start. After the process 600 starts, at block 620, the sensed supply 410b can be set to the upper voltage threshold target, such as 0.8 volts. After the sensed supply 410 b is set, at block 630, the up threshold programmability engine 420b can output a voltage and sweep the output voltage from zero volts to the full scale of volts. While the up threshold programmability engine 420b is sweeping the output voltage, the high flag comparator 440b will output a high flag 445b when the voltage on the up voltage (V_{UP}) threshold line 470b goes higher than the reference voltage (Vref) 460. At decision block 640, one or more processors (or a tester) can determine whether, during the sweeping of the output voltage, the high flag comparator 440b outputted a high flag 445b. If the one or more processors determine that the high flag comparator 440b did not output a high flag 445b during the sweeping of the output voltage, the process 600 can proceed back to block 630.

However, if the one or more processors determine that the high flag comparator 440b did output a high flag 445b during the sweeping of the output voltage, at block 650, a code (e.g., a bit code, such as a seven bit code) of the up threshold programmability engine 420b, which corresponds to the output voltage of the up threshold programmability engine 420b to make the high flag comparator 440b output a high flag 445b, can be fused for the up threshold programmability engine 420b. After the code of the up threshold programmability engine 420b is fused, at block 660, the comparator high threshold calibration is done.

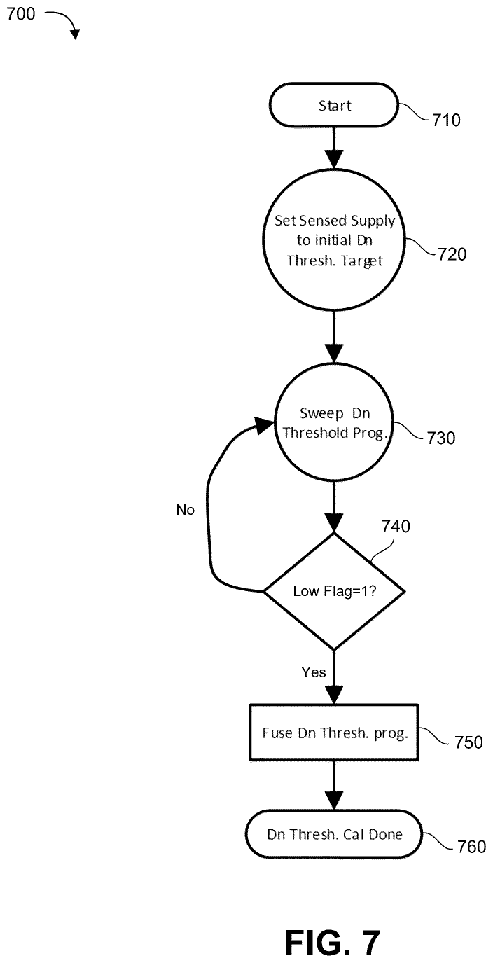

FIG. 7 is a flow diagram illustrating a process 700 for calibrating a comparator down threshold (e.g., the lower voltage threshold (vth_lower)). The lower voltage threshold (vth_lower), such as 0.2 volts, may be set by the customer of the device. However, the desired lower voltage threshold (vth_lower), such as 0.2 volts, may be too low for accurate testing by the test equipment. For this reason, an alternative voltage level (e.g., a lower threshold voltage target), such as 0.4 volts, which is close to the desired lower voltage threshold (vth_lower), may be used for testing purposes.

During operation of the process 700 of FIG. 7, at block 710, the process 700 can start. After the process 700 starts, at block 720, the sensed supply 410a can be set to the lower voltage threshold target, such as 0.4 volts. After the sensed supply 410 a is set, at block 730, the down threshold programmability engine 420a can output a voltage and sweep the output voltage from the full scale of volts to zero volts. While the down threshold programmability engine 420a is sweeping the output voltage, the low flag comparator 440a will output a low flag 445a when the voltage on the down voltage (V_{DN}) threshold line 470a goes lower than the reference voltage (Vref) 460. At decision block 740, one or more processors (or a tester) can determine whether, during the sweeping of the output voltage, the low flag comparator 440a outputted a low flag 445a. If the one or more processors determine that the low flag comparator 440a did not output a low flag 445a during the sweeping of the output voltage, the process 700 can proceed back to block 730.

However, if the one or more processors determine that the low flag comparator 440a did output a low flag 445a during the sweeping of the output voltage, at block 750, a code (e.g., a bit code, such as a seven bit code) of the down threshold programmability engine 420a, which corresponds to the output voltage of the down threshold programmability engine 420a to make the low flag comparator 440a output a low flag 445a, can be fused for the down threshold programmability engine 420a. After the code of the down threshold programmability engine 420a is fused, at block 760, the comparator low threshold calibration is done.

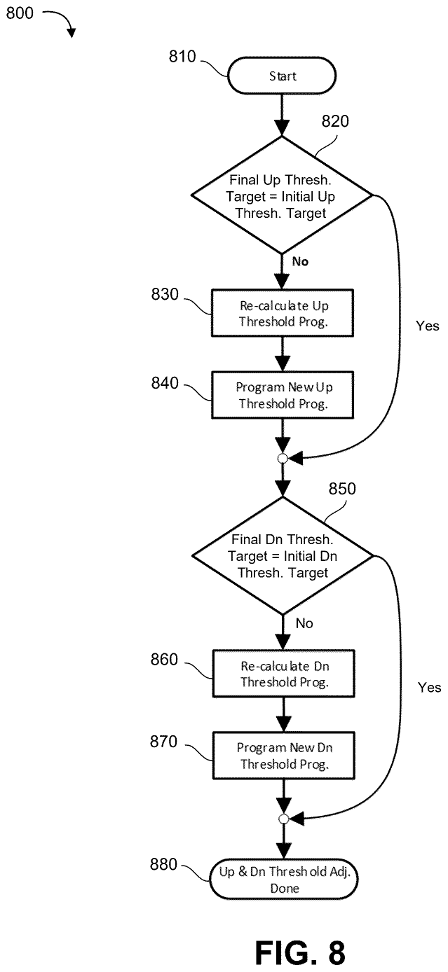

FIG. 8 is a flow diagram illustrating a process 800 for adjusting a comparator up threshold and/or a comparator down threshold. When, during the operation of process 600 and/or process 700, an alternative voltage level (e.g., an upper threshold target and/or a lower threshold voltage target) is used for testing purposes, the process 800 can be used to adjust the comparator up threshold and/or the comparator down threshold, accordingly.

For example, during the process 600, an upper threshold target (e.g., 0.8 volts) was used for testing purposes instead of the desired upper voltage threshold (vth_upper) (e.g., 0.9 volts). The process 800 can be used to adjust the calibration of the comparator down threshold. For another example, during the process 700, a lower threshold target (e.g., 0.4 volts) was used for testing purposes instead of the desired lower voltage threshold (vth_lower) (e.g., 0.2 volts). The process 800 can be used to adjust the calibration of the comparator up threshold.

During operation of the process 800, at block 810, the process 800 can start. After the process 800 starts, at block 820, one or more processors can determine whether the upper threshold target (e.g., 0.8 volts) is close to (e.g., within a threshold difference from) the initial desired upper voltage threshold (vth_upper) (e.g., 0.9 volts). If the one or more processors determine that the upper threshold target is close to (e.g., within a threshold difference from) the initial desired upper voltage threshold (vth_upper), the process 800 can proceed to decision block 850.

However, if the one or more processors determine that the upper threshold target (e.g., 0.8 volts) is not close to (e.g., within a threshold difference from) the initial desired upper voltage threshold (vth_upper) (e.g., 0.9 volts), at block 830, the one or more processors can re-calculate the code (e.g., to get an updated code) for the up threshold programmability engine 420b. In one or more examples, the updated code can be calculated to be equal to the previously calculated code (e.g., obtained from process 600 of FIG. 6) times the initial desired upper voltage threshold (vth_upper) voltage (e.g., 0.9 volts) divided by the upper threshold target voltage (e.g., 0.8 volts). As such, for example, the updated code=previous code*(0.9/0.8).

After the updated code has been calculated, at block 840, the updated code can be stored on or using software for the up threshold programmability engine 420b. After the updated code of the up threshold programmability engine 420b is stored on software, the process 800 can proceed to decision block 850.

At decision block 850, the one or more processors can determine whether the lower threshold target (e.g., 0.4 volts) is close to (e.g., within a threshold difference from) the initial desired lower voltage threshold (vth_lower) (e.g., 0.2 volts). If the one or more processors determine that the lower threshold target is close to (e.g., within a threshold difference from) the initial desired lower voltage threshold (vth_lower), the process 800 can proceed to block 880.

However, if the one or more processors determine that the lower threshold target (e.g., 0.4 volts) is not close to (e.g., within a threshold difference from) the initial desired lower voltage threshold (vth_lower) (e.g., 0.2 volts), at block 860, the one or more processors can re-calculate the code (e.g., to get an updated code) for the down threshold programmability engine 420a. In one or more examples, the updated code can be calculated to be equal to the previously calculated code (e.g., obtained from process 700 of FIG. 7) times the initial desired lower voltage threshold (vth_lower) voltage (e.g., 0.2 volts) divided by the lower threshold target voltage (e.g., 0.4 volts). As such, for example, the updated code=previous code*(0.2/0.4).

After the updated code has been calculated, at block 870, the updated code can be stored on or using software for the down threshold programmability engine 420a. After the updated code of the down threshold programmability engine 420a is stored on software, the process 800 can proceed to block 880. At block 880, the adjustment for the comparator up threshold and/or the comparator down threshold is done.

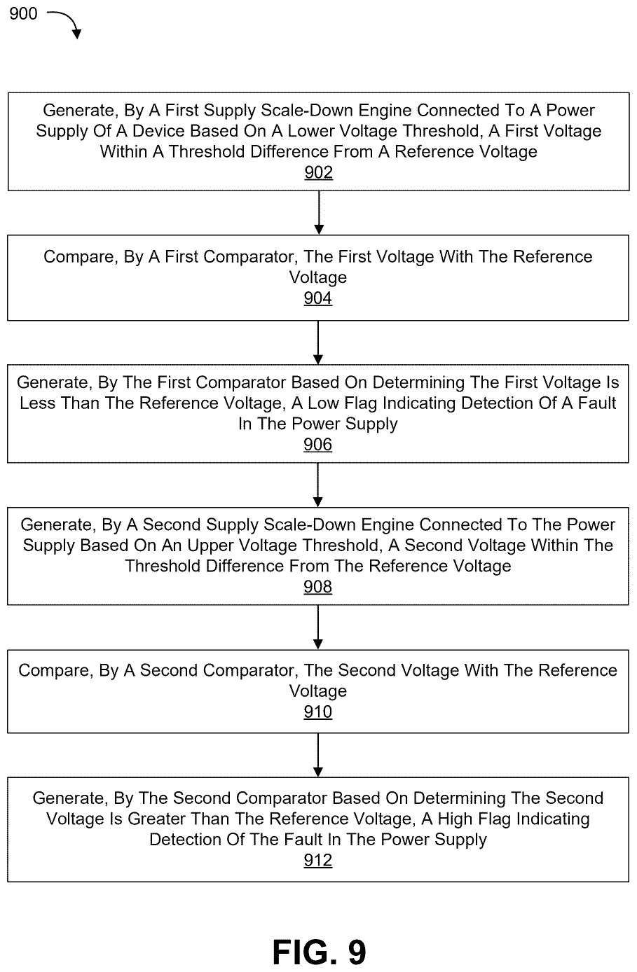

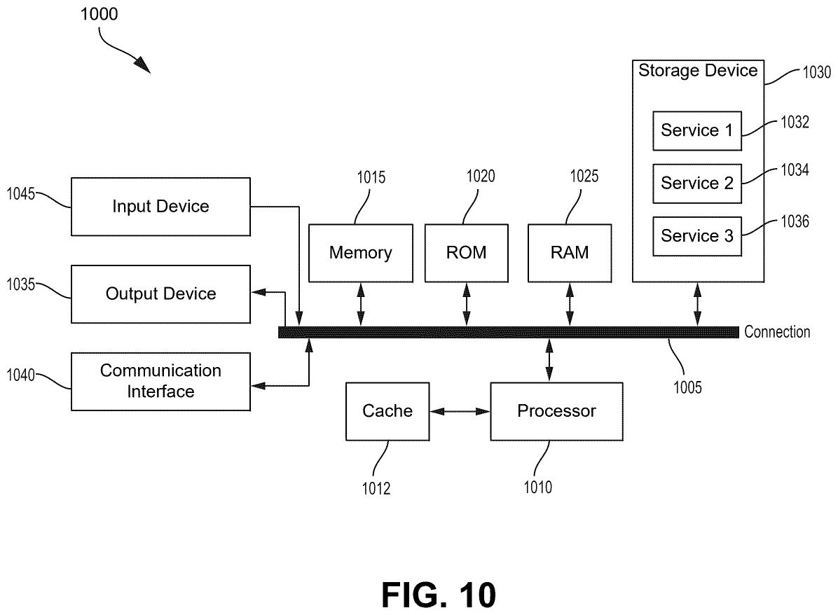

FIG. 9 is a flow chart illustrating an example of a process 900 for detecting a fault (e.g., a glitch) in a power supply. The process 900 can be performed by a computing device (e.g., a computing device or computing system 1000 of FIG. 10) or by a component or system (e.g., a chipset, one or more processors central processing units (CPUs), digital signal processors (DSPs), graphics processing units (GPUs), any combination thereof, and/or other type of processor(s), or other component or system) of the computing device. The operations of the process 900 may be implemented as software components that are executed and run on one or more processors (e.g., processor 1010 of FIG. 10, or other processor(s)). Further, the transmission and reception of signals by the computing device in the process 900 may be enabled, for example, by one or more antennas and/or one or more transceivers (e.g., wireless transceiver(s)).

At block 902, the computing device (or component thereof) can generate, using a first supply scale-down engine connected to a power supply of a device based on a lower voltage threshold, a first voltage within a threshold difference from a reference voltage. In some aspects, the computing device (or component thereof) can generate the reference voltage using a reference programmability engine of the device.

At block 904, the computing device (or component thereof) can compare, using a first comparator, the first voltage with the reference voltage. In some cases, the computing device (or component thereof) can monitor, using the first comparator, the first voltage at every clock cycle of a system clock of the device.

At block 906, the computing device (or component thereof) can generate, by the first comparator based on determining the first voltage is less than the reference voltage, a low flag indicating detection of a fault in the power supply.

At block 908, the computing device (or component thereof) can generate, using a second supply scale-down engine connected to the power supply based on an upper voltage threshold, a second voltage within the threshold difference from the reference voltage. In some aspects, the reference voltage is less than the lower voltage threshold and the upper voltage threshold.

At block 910, the computing device (or component thereof) can compare, using a second comparator, the second voltage with the reference voltage. In some cases, the computing device (or component thereof) can monitor, using the second comparator, the second voltage at every clock cycle of the system clock.

At block 912, the computing device (or component thereof) can generate, using the second comparator based on determining the second voltage is greater than the reference voltage, a high flag indicating detection of the fault in the power supply.

In some aspects, the computing device (or component thereof) can measure, during performing a code sweep by the reference programmability engine, voltage at a reference voltage node to obtain a measured reference voltage. The computing device (or component thereof) can determine, based on determining the measured reference voltage is within a threshold difference from a target reference voltage, a corresponding code for the reference programmability engine. The computing device (or component thereof) can fuse the code for the reference programmability engine.

In some aspects, the computing device (or component thereof) can set the power supply to an upper threshold target voltage. The computing device (or component thereof) can perform, using the second supply scale-down engine, a code sweep. The computing device (or component thereof) can determine, based on determining the second comparator generates the high flag during the code sweep, a code corresponding to the second supply scale-down engine. The computing device (or component thereof) can then fuse the code for the second supply scale-down engine. In some cases, the code sweep is from a value of 0 to a full-scale value of the second supply scale-down engine. In some aspects, the computing device (or component thereof) can determine, based on determining the upper threshold target voltage is not equal to the upper voltage threshold, an adjusted code for the second supply scale-down engine based on a ratio of the upper voltage threshold over the upper threshold target voltage.

In some aspects, the computing device (or component thereof) can set the power supply to a lower threshold target voltage. The computing device (or component thereof) can perform, using the first supply scale-down engine, a code sweep. The computing device (or component thereof) can determine, based on determining the first comparator generates the low flag during the code sweep, a code corresponding to the first supply scale-down engine. The computing device (or component thereof) can fuse the code for the first supply scale-down engine. In some cases, the code sweep is from a value of 0 to a full-scale value of the first supply scale-down engine. In some aspects, the computing device (or component thereof) can determine, based on determining the lower threshold target voltage is not equal to the lower voltage threshold, an adjusted code for the first supply scale-down engine based on a ratio of the lower voltage threshold over the lower threshold target voltage.

In some cases, the computing device of process 900 may include various components, such as one or more input devices, one or more output devices, one or more processors, one or more microprocessors, one or more microcomputers, one or more cameras, one or more sensors, and/or other component(s) that are configured to carry out the steps of processes described herein. In some examples, the computing device may include a display, one or more network interfaces configured to communicate and/or receive the data, any combination thereof, and/or other component(s). The one or more network interfaces may be configured to communicate and/or receive wired and/or wireless data, including data according to the 3G, 4G, 5G, and/or other cellular standard, data according to the Wi-Fi (802.11x) standards, data according to the Bluetooth™ standard, data according to the Internet Protocol (IP) standard, and/or other types of data.

The components of the computing device of process 900 can be implemented in circuitry. For example, the components can include and/or can be implemented using electronic circuits or other electronic hardware, which can include one or more programmable electronic circuits (e.g., microprocessors, graphics processing units (GPUs), digital signal processors (DSPs), central processing units (CPUs), and/or other suitable electronic circuits), and/or can include and/or be implemented using computer software, firmware, or any combination thereof, to perform the various operations described herein. The computing device may further include a display (as an example of the output device or in addition to the output device), a network interface configured to communicate and/or receive the data, any combination thereof, and/or other component(s). The network interface may be configured to communicate and/or receive Internet Protocol (IP) based data or other type of data.

The process 900 is illustrated as a logical flow diagram, the operations of which represent a sequence of operations that can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

Additionally, the process 900 may be performed under the control of one or more computer systems configured with executable instructions and may be implemented as code (e.g., executable instructions, one or more computer programs, or one or more applications) executing collectively on one or more processors, by hardware, or combinations thereof. As noted above, the code may be stored on a computer-readable or machine-readable storage medium, for example, in the form of a computer program comprising a plurality of instructions executable by one or more processors. The computer-readable or machine-readable storage medium may be non-transitory.

FIG. 10 is a block diagram illustrating an example of a computing system 1000, which may be employed for a high speed comparator-based supply glitch detector. In particular, FIG. 10 illustrates an example of computing system 1000, which can be for example any computing device making up internal computing system, a remote computing system, a camera, or any component thereof in which the components of the system are in communication with each other using connection 1005. Connection 1005 can be a physical connection using a bus, or a direct connection into processor 1010, such as in a chipset architecture. Connection 1005 can also be a virtual connection, networked connection, or logical connection.

In some aspects, computing system 1000 is a distributed system in which the functions described in this disclosure can be distributed within a datacenter, multiple data centers, a peer network, etc. In some aspects, one or more of the described system components represents many such components each performing some or all of the function for which the component is described. In some aspects, the components can be physical or virtual devices.

Example system 1000 includes at least one processing unit (CPU or processor) 1010 and connection 1005 that communicatively couples various system components including system memory 1015, such as read-only memory (ROM) 1020 and random access memory (RAM) 1025 to processor 1010. Computing system 1000 can include a cache 1012 of high-speed memory connected directly with, in close proximity to, or integrated as part of processor 1010.

Processor 1010 can include any general purpose processor and a hardware service or software service, such as services 1032, 1034, and 1036 stored in storage device 1030, configured to control processor 1010 as well as a special-purpose processor where software instructions are incorporated into the actual processor design. Processor 1010 may essentially be a completely self-contained computing system, containing multiple cores or processors, a bus, memory controller, cache, etc. A multi-core processor may be symmetric or asymmetric.

To enable user interaction, computing system 1000 includes an input device 1045, which can represent any number of input mechanisms, such as a microphone for speech, a touch-sensitive screen for gesture or graphical input, keyboard, mouse, motion input, speech, etc. Computing system 1000 can also include output device 1035, which can be one or more of a number of output mechanisms. In some instances, multimodal systems can enable a user to provide multiple types of input/output to communicate with computing system 1000.

Computing system 1000 can include communications interface 1040, which can generally govern and manage the user input and system output. The communication interface may perform or facilitate receipt and/or transmission wired or wireless communications using wired and/or wireless transceivers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

The communications interface 1040 may also include one or more range sensors (e.g., LiDAR sensors, laser range finders, RF radars, ultrasonic sensors, and infrared (IR) sensors) configured to collect data and provide measurements to processor 1010, whereby processor 1010 can be configured to perform determinations and calculations needed to obtain various measurements for the one or more range sensors. In some examples, the measurements can include time of flight, wavelengths, azimuth angle, elevation angle, range, linear velocity and/or angular velocity, or any combination thereof. The communications interface 1040 may also include one or more Global Navigation Satellite System (GNSS) receivers or transceivers that are used to determine a location of the computing system 1000 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1030 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1(L 1 ) cache, Level 2(L 2 ) cache, Level 3(L 3 ) cache, Level 4(L 4 ) cache, Level 5(L 5 ) cache, or other (L#) cache), resistive random-access memory (RRAM/ReRAM), phase change memory (PCM), spin transfer torque RAM (STT-RAM), another memory chip or cartridge, and/or a combination thereof.

The storage device 1030 can include software services, servers, services, etc., that when the code that defines such software is executed by the processor 1010, it causes the system to perform a function. In some aspects, a hardware service that performs a particular function can include the software component stored in a computer-readable medium in connection with the necessary hardware components, such as processor 1010, connection 1005, output device 1035, etc., to carry out the function. The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the aspects and examples provided herein, but those skilled in the art will recognize that the application is not limited thereto. Thus, while illustrative aspects of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, aspects can be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate aspects, the methods may be performed in a different order than that described.

For clarity of explanation, in some instances the present technology may be presented as including individual functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the aspects in unnecessary detail. In other instances, well-known circuits, processes, algorithms, structures, and techniques may be shown without unnecessary detail in order to avoid obscuring the aspects.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual aspects may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general purpose computer, special purpose computer, or a processing device to perform a certain function or group of functions. Portions of computer resources used can be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some aspects the computer-readable storage devices, mediums, and memories can include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the methods, algorithms, and/or operations described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

One of ordinary skill will appreciate that the less than (“<”) and greater than (“>”) symbols or terminology used herein can be replaced with less than or equal to (“≤”) and greater than or equal to (“≥”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The various illustrative logical blocks, modules, engines, circuits, and algorithm steps described in connection with the embodiments disclosed herein may be implemented as electronic hardware, computer software, firmware, or combinations thereof. To clearly illustrate this interchangeability of hardware and software, various illustrative components, blocks, engines, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as engines, modules, or components may be implemented together in an integrated logic device or separately as discrete but interoperable logic devices. If implemented in software, the techniques may be realized at least in part by a computer-readable data storage medium comprising program code including instructions that, when executed, performs one or more of the methods described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein. In addition, in some aspects, the functionality described herein may be provided within dedicated software modules or hardware modules configured for encoding and decoding, or incorporated in a combined video encoder-decoder (CODEC).

Illustrative aspects of the disclosure include:
Aspect 1. A method of detecting faults, the method comprising: generating, by a first supply scale-down engine connected to a power supply of a device based on a lower voltage threshold, a first voltage within a threshold difference from a reference voltage; comparing, by a first comparator, the first voltage with the reference voltage; generating, by the first comparator based on determining the first voltage is less than the reference voltage, a low flag indicating detection of a fault in the power supply; generating, by a second supply scale-down engine connected to the power supply based on an upper voltage threshold, a second voltage within the threshold difference from the reference voltage; comparing, by a second comparator, the second voltage with the reference voltage; and generating, by the second comparator based on determining the second voltage is greater than the reference voltage, a high flag indicating detection of the fault in the power supply.
Aspect 2. The method of Aspect 1, further comprising generating, by a reference programmability engine of the device, the reference voltage.
Aspect 3. The method of Aspect 2, further comprising measuring, during performing a code sweep by the reference programmability engine, voltage at a reference voltage node to obtain a measured reference voltage; determining, based on determining the measured reference voltage is within a threshold difference from a target reference voltage, a corresponding code for the reference programmability engine; and fusing the code for the reference programmability engine.
Aspect 4. The method of any of Aspects 1 to 3, wherein the reference voltage is less than the lower voltage threshold and the upper voltage threshold.
Aspect 5. The method of any of Aspects 1 to 4, further comprising: monitoring, by the first comparator, the first voltage at every clock cycle of a system clock of the device, and monitoring, by the second comparator, the second voltage at every clock cycle of the system clock.
Aspect 6. The method of any of Aspects 1 to 5, further comprising: setting the power supply to an upper threshold target voltage; performing, by the second supply scale-down engine, a code sweep; determining, based on determining the second comparator generates the high flag during the code sweep, a code corresponding to the second supply scale-down engine; and fusing the code for the second supply scale-down engine.
Aspect 7. The method of Aspect 6, wherein the code sweep is from a value of 0 to a full-scale value of the second supply scale-down engine.
Aspect 8. The method of any of Aspects 6 or 7, further comprising determining, based on determining the upper threshold target voltage is not equal to the upper voltage threshold, an adjusted code for the second supply scale-down engine based on a ratio of the upper voltage threshold over the upper threshold target voltage.
Aspect 9. The method of any of Aspects 1 to 8, further comprising: setting the power supply to a lower threshold target voltage; performing, by the first supply scale-down engine, a code sweep; determining, based on determining the first comparator generates the low flag during the code sweep, a code corresponding to the first supply scale-down engine; and fusing the code for the first supply scale-down engine.
Aspect 10. The method of Aspect 9, wherein the code sweep is from a value of 0 to a full-scale value of the first supply scale-down engine.
Aspect 11. The method of any of Aspects 9 or 10, further comprising determining, based on determining the lower threshold target voltage is not equal to the lower voltage threshold, an adjusted code for the first supply scale-down engine based on a ratio of the lower voltage threshold over the lower threshold target voltage.
Aspect 12. An apparatus for detecting faults, the apparatus comprising: a power supply; a first supply scale-down engine connected to the power supply, the first supply scale-down engine configured to generate, based on a lower voltage threshold, a first voltage within a threshold difference from a reference voltage; a first comparator configured to: compare the first voltage with the reference voltage; and generate, based on the first voltage being less than the reference voltage, a low flag indicating detection of a fault in the power supply; a second supply scale-down engine connected to the power supply, the second supply scale-down engine configured to generate, based on an upper voltage threshold, a second voltage within the threshold difference from the reference voltage; and a second comparator configured to: compare the second voltage with the reference voltage; and generate, based on the second voltage being is greater than the reference voltage, a high flag indicating detection of the fault in the power supply.
Aspect 13. The apparatus of Aspect 12, further comprising a reference programmability engine configured to generate the reference voltage.
Aspect 14. The apparatus of Aspect 13, further comprising at least one processor configured to: measure, during a code sweep performed by the reference programmability engine, voltage at a reference voltage node to obtain a measured reference voltage; determine, based on the measured reference voltage being within a threshold difference from a target reference voltage, a corresponding code for the reference programmability engine; and fuse the code for the reference programmability engine.
Aspect 15. The apparatus of any of Aspects 12 to 14, wherein the reference voltage is less than the lower voltage threshold and the upper voltage threshold.
Aspect 16. The apparatus of any of Aspects 12 to 15, wherein: the first comparator is configured to monitor the first voltage at every clock cycle of a system clock of the apparatus, and the second comparator is configured to monitor the second voltage at every clock cycle of the system clock.
Aspect 17. The apparatus of any of Aspects 12 to 16, wherein the second supply scale-down engine is configured to perform a code sweep, and further comprising at least one processor configured to: set the power supply to an upper threshold target voltage; determine, based on a determination that the second comparator generates the high flag during the code sweep, a code corresponding to the second supply scale-down engine; and fuse the code for the second supply scale-down engine.
Aspect 18. The apparatus of Aspect 17, wherein the code sweep is from a value of 0 to a full-scale value of the second supply scale-down engine.
Aspect 19. The apparatus of any of Aspects 17 or 18, further comprising at least one processor configured to: determine, based on the upper threshold target voltage not being equal to the upper voltage threshold, an adjusted code for the second supply scale-down engine based on a ratio of the upper voltage threshold over the upper threshold target voltage.
Aspect 20. The apparatus of any of Aspects 12 to 19, wherein the first supply scale-down engine is configured to perform a code sweep, and further comprising at least one processor configured to: set the power supply to a lower threshold target voltage; determine, based on a determination that the first comparator generates the low flag during the code sweep, a code corresponding to the first supply scale-down engine; and fuse the code for the first supply scale-down engine.
Aspect 21. The apparatus of Aspect 20, wherein the code sweep is from a value of 0 to a full-scale value of the first supply scale-down engine.
Aspect 22. The apparatus of any of Aspects 20 or 21, further comprising at least one processor configured to: determine, based on the lower threshold target voltage not being equal to the lower voltage threshold, an adjusted code for the first supply scale-down engine based on a ratio of the lower voltage threshold over the lower threshold target voltage.
Aspect 23. A non-transitory computer-readable medium having stored thereon instructions that, when executed by at least one processor, cause the at least one processor to perform operations according to any of Aspects 12 to 22.
Aspect 24. An apparatus for detecting faults, the apparatus including one or more means for performing operations according to any of Aspects 12 to 22.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.”

What is claimed is:

1. A method of detecting faults, the method comprising:
generating, by a first supply scale-down engine connected to a power supply of a device based on a lower voltage threshold, a first voltage within a threshold difference from a reference voltage;
comparing, by a first comparator, the first voltage with the reference voltage;
generating, by the first comparator based on determining the first voltage is less than the reference voltage, a low flag indicating detection of a fault in the power supply;
generating, by a second supply scale-down engine connected to the power supply based on an upper voltage threshold, a second voltage within the threshold difference from the reference voltage;
comparing, by a second comparator, the second voltage with the reference voltage; and
generating, by the second comparator based on determining the second voltage is greater than the reference voltage, a high flag indicating detection of the fault in the power supply.

2. The method of claim 1, further comprising generating, by a reference programmability engine of the device, the reference voltage.

3. The method of claim 2, further comprising measuring, during performing a code sweep by the reference programmability engine, voltage at a reference voltage node to obtain a measured reference voltage;
determining, based on determining the measured reference voltage is within a threshold difference from a target reference voltage, a corresponding code for the reference programmability engine; and
fusing the code for the reference programmability engine.

4. The method of claim 1, wherein the reference voltage is less than the lower voltage threshold and the upper voltage threshold.

5. The method of claim 1, further comprising:
monitoring, by the first comparator, the first voltage at every clock cycle of a system clock of the device, and
monitoring, by the second comparator, the second voltage at every clock cycle of the system clock.

6. The method of claim 1, further comprising:
setting the power supply to an upper threshold target voltage;
performing, by the second supply scale-down engine, a code sweep;
determining, based on determining the second comparator generates the high flag during the code sweep, a code corresponding to the second supply scale-down engine; and
fusing the code for the second supply scale-down engine.

7. The method of claim 6, wherein the code sweep is from a value of 0 to a full-scale value of the second supply scale-down engine.

8. The method of claim 6, further comprising determining, based on determining the upper threshold target voltage is not equal to the upper voltage threshold, an adjusted code for the second supply scale-down engine based on a ratio of the upper voltage threshold over the upper threshold target voltage.

9. The method of claim 1, further comprising:
setting the power supply to a lower threshold target voltage;
performing, by the first supply scale-down engine, a code sweep;
determining, based on determining the first comparator generates the low flag during the code sweep, a code corresponding to the first supply scale-down engine; and
fusing the code for the first supply scale-down engine.

10. The method of claim 9, wherein the code sweep is from a value of 0 to a full-scale value of the first supply scale-down engine.

11. The method of claim 9, further comprising determining, based on determining the lower threshold target voltage is not equal to the lower voltage threshold, an adjusted code for the first supply scale-down engine based on a ratio of the lower voltage threshold over the lower threshold target voltage.

12. An apparatus for detecting faults, the apparatus comprising:
a power supply;
a first supply scale-down engine connected to the power supply, the first supply scale-down engine configured to generate, based on a lower voltage threshold, a first voltage within a threshold difference from a reference voltage;
a first comparator configured to:
compare the first voltage with the reference voltage; and
generate, based on the first voltage being less than the reference voltage, a low flag indicating detection of a fault in the power supply;
a second supply scale-down engine connected to the power supply, the second supply scale-down engine configured to generate, based on an upper voltage threshold, a second voltage within the threshold difference from the reference voltage; and
a second comparator configured to:
compare the second voltage with the reference voltage; and
generate, based on the second voltage being is greater than the reference voltage, a high flag indicating detection of the fault in the power supply.

13. The apparatus of claim 12, further comprising a reference programmability engine configured to generate the reference voltage.

14. The apparatus of claim 13, further comprising at least one processor configured to:
measure, during a code sweep performed by the reference programmability engine, voltage at a reference voltage node to obtain a measured reference voltage;
determine, based on the measured reference voltage being within a threshold difference from a target reference voltage, a corresponding code for the reference programmability engine; and
fuse the code for the reference programmability engine.

15. The apparatus of claim 12, wherein the reference voltage is less than the lower voltage threshold and the upper voltage threshold.

16. The apparatus of claim 12, wherein:
the first comparator is configured to monitor the first voltage at every clock cycle of a system clock of the apparatus, and
the second comparator is configured to monitor the second voltage at every clock cycle of the system clock.

17. The apparatus of claim 12, wherein the second supply scale-down engine is configured to perform a code sweep, and further comprising at least one processor configured to:
set the power supply to an upper threshold target voltage;
determine, based on a determination that the second comparator generates the high flag during the code sweep, a code corresponding to the second supply scale-down engine; and
fuse the code for the second supply scale-down engine.

18. The apparatus of claim 17, further comprising at least one processor configured to:
determine, based on the upper threshold target voltage not being equal to the upper voltage threshold, an adjusted code for the second supply scale-down engine based on a ratio of the upper voltage threshold over the upper threshold target voltage.

19. The apparatus of claim 12, wherein the first supply scale-down engine is configured to perform a code sweep, and further comprising at least one processor configured to:
set the power supply to a lower threshold target voltage;
determine, based on a determination that the first comparator generates the low flag during the code sweep, a code corresponding to the first supply scale-down engine; and
fuse the code for the first supply scale-down engine.

20. The apparatus of claim 19, further comprising at least one processor configured to:
determine, based on the lower threshold target voltage not being equal to the lower voltage threshold, an adjusted code for the first supply scale-down engine based on a ratio of the lower voltage threshold over the lower threshold target voltage.
